(19) United States
(12) Patent Application Publication
(10) Pub. No.: US 2023/0047113 A1
(43) Pub. Date: Feb. 16, 2023

(54) POLISHING DEVICE AND METHOD FOR MANUFACTURING SEMICONDUCTOR DEVICE

(71) Applicant: SKC solmics Co., Ltd., Gyeonggi-do (KR)

(72) Inventors: Jae In AHN, Gyeonggi-do (KR); Jong Wook YUN, Seoul (KR); Eun Sun JOENG, Gyeonggi-do (KR); Jang Won SEO, Seoul (KR)

(21) Appl. No.: 17/886,529

(22) Filed: Aug. 12, 2022

(30) Foreign Application Priority Data
Aug. 13, 2021 (KR) 10-2021-0107178

(51) Int. Cl. H01L 21/304; B24B 57/02; B24B 37/005

(52) U.S. Cl. CPC H01L 21/304; B24B 57/02; B24B 37/005; H01L 21/3212

(57) ABSTRACT

Provided are a polishing device including: a surface plate; a polishing pad mounted on the surface plate; a carrier for accommodating a polishing object; and a slurry supply unit including at least one nozzle, wherein the carrier performs a vibrating motion in a trajectory from the center of the surface plate to the end of the surface plate, and the slurry supply unit performs a vibrating motion at the same trajectory and speed as those of the vibrating motion of the carrier, as a polishing device which includes a slurry supply unit enabling subdivided driving in the supply of a polishing slurry, and in which the driving of the slurry supply unit has an advantage enabling optimized driving in an organic relationship between rotation and/or vibrating motion of the carrier and the surface plate and vertical pressurization conditions, etc. for the polishing surface of the carrier.

### CROSS-REFERENCE TO RELATED APPLICATION(S)

This application claims priority to Korean Patent Application No. 10-2021-0107178, filed on Aug. 13, 2021, the disclosure of which is incorporated herein by reference in its entirety.

### TECHNICAL FIELD

The present disclosure relates to a polishing device applied to a polishing process, and to a technique for applying the same to a method for manufacturing a semiconductor device.

### DESCRIPTION OF THE RELATED ART

A chemical mechanical planarization (CMP) or chemical mechanical polishing (CMP) process may be performed for various purposes in various technical fields. The CMP process is performed on a predetermined polishing surface of a polishing object, and may be performed for the purposes of planarization of the polishing surface, removal of agglomerated materials, resolution of crystal lattice damage, removal of scratches and pollution source, etc.

The CMP process technology of the semiconductor process may be classified depending on a polishing object film or the surface shape after polishing. For example, it may be classified into CMP processes of various oxide films divided into single silicon or polysilicon depending on the polishing object film and divided depending on the type of impurities, or CMP processes of metal films such as tungsten (W), copper (Cu), aluminum (Al), ruthenium (Ru), tantalum (Ta), etc. In addition, depending on the surface shape after polishing, it may be classified into a process of alleviating the roughness of the substrate surface, a process of flattening a step difference caused by multilayer circuit wiring, and an element isolation process for selectively forming circuit wiring after polishing.

The CMP process may be applied in plurality in the process of manufacturing a semiconductor device. The semiconductor device includes a plurality of layers, and each layer contains a complicated and fine circuit pattern. Further, semiconductor devices have recently been evolving in a direction that individual chip sizes are reduced, and a pattern of each layer becomes more complicated and finer. Accordingly, in the process of manufacturing the semiconductor device, the purpose of the CMP process has been expanded to not only the purpose of planarizing circuit wiring, but also the purpose of applying separation of circuit wiring and improvement of wiring surface, and as a result, more sophisticated and reliable CMP performance is required.

### SUMMARY

In one embodiment of the present disclosure, an object of the present disclosure is to provide a polishing device capable of fine and sophisticated design of the process. Specifically, an object of the present disclosure is to provide a polishing device enabling optimized driving in an organic relationship between rotation and/or vibrating motion of a carrier and a surface plate and vertical pressurization conditions, etc., by being provided with a slurry supply unit enabling subdivided driving in the supply of a polishing slurry.

In another embodiment of the present disclosure, an object of the present disclosure is to provide a method for manufacturing a semiconductor device, to which the polishing device is applied. In manufacturing a semiconductor device, sophisticated process control is very important compared to other products, and an object of the present disclosure is to provide a technical means capable of obtaining a high-quality semiconductor device by applying the polishing device, thereby providing a polishing process that meets such a requirement.

In one embodiment, there is provided a polishing device including: a surface plate; a polishing pad mounted on the surface plate; a carrier for accommodating a polishing object; and a slurry supply unit including at least one nozzle, wherein the carrier performs a vibrating motion in a trajectory from the center of the surface plate to the end of the surface plate, and the slurry supply unit performs a vibrating motion at the same trajectory and speed as those of the vibrating motion of the carrier.

The carrier may have a circular shaped plane, the slurry supply unit may have a circular arc shaped plane, and the slurry supply unit may be formed in a form corresponding to a peripheral shape of the carrier.

The slurry supply unit may have a radius of curvature of 4 inches to 30 inches, and the carrier may have a diameter of 100 mm to 400 mm.

The polishing pad may include a polishing layer having a polishing surface, the polishing surface may include at least one groove having a depth smaller than a thickness of the polishing layer, the groove may have a depth of 100 μm to 1,500 μm, and the groove may have a width of 100 μm to 1,000 μm.

The polishing pad may include a polishing layer having a polishing surface, the polishing surface may include two or more grooves having a depth smaller than the thickness of the polishing layer, and two adjacent grooves may have a pitch therebetween of 2 mm to 70 mm.

The polishing pad may include a polishing layer having a polishing surface, the polishing layer may include a cured product of a preliminary composition comprising a urethane-based prepolymer, and the preliminary composition may have an isocyanate group content (NCO%) of 5% by weight to 11% by weight.

In another embodiment, there is provided a method for manufacturing a semiconductor device, the method comprising steps of: mounting a polishing pad on a surface plate; mounting a polishing object on a carrier; disposing a polishing surface of the polishing pad and a surface to be polished of the polishing object to be in contact with each other and then respectively rotating the surface plate and the carrier under pressurized conditions to polish the polishing object; and supplying a slurry onto the polishing surface of the polishing pad from a slurry supply unit including at least one nozzle, wherein the polishing object includes a semiconductor substrate, the carrier performs a vibrating motion in a trajectory from the center of the surface plate to the end of the surface plate, and the slurry supply unit performs a vibrating motion at the same trajectory and speed as those of the vibrating motion of the carrier.

The slurry supply unit may include a plurality of nozzles, and the amount of the slurry injected through each nozzle may be independently adjusted in a range of 0 ml/min to 1,000 ml/min.

The surface plate may have a rotation speed of 50 rpm to 150 rpm.

The carrier may have a rotation speed of 10 rpm to 500 rpm.

The polishing device has a slurry supply unit enabling subdivided driving in the supply of the polishing slurry, and thus has the advantage of enabling optimized driving in an organic relationship between rotation and/or vibrating motion of the carrier and the surface plate and the vertical pressurization conditions, etc.

Further, the method for manufacturing a semiconductor device, to which the polishing device is applied, can be an effective technical means of obtaining a high-quality semiconductor device by providing optimal polishing performance in manufacturing of a semiconductor device, in which sophisticated process control is very important compared to other products.

### BRIEF DESCRIPTION OF THE DRAWINGS

FIG. 1 schematically illustrates a perspective view of the polishing device according to one embodiment.

FIG. 2 schematically illustrates a plan view of the polishing device according to one embodiment.

FIG. 3 schematically illustrates a cross section in the thickness direction of the polishing pad according to one embodiment.

FIG. 4 is a schematic diagram illustrating an enlarged portion A of FIG. 3.

### DESCRIPTION OF SPECIFIC EMBODIMENTS

Advantages and features of the present disclosure, and methods for achieving them will become apparent with reference to embodiments to be described later. However, the present disclosure is not limited to the embodiments disclosed below, but will be implemented in various different forms, and only the present embodiments allow the disclosure of the present disclosure to be complete, and are provided to inform those of ordinary skills in the art to which the present disclosure pertains of the scope of the invention, and the present disclosure is only defined by the scope of the claims.

In order to clearly express various layers and regions in the drawings, the thicknesses are enlarged and shown. Further, in the drawings, the thickness of some layers and regions is exaggerated for convenience of description. The same reference numerals refer to the same elements throughout the specification.

Further, in the present specification, when a part of a layer, film, region, plate, or the like is said to be “above” or “on” other part, this not only includes a case where the part is “directly above” the other part, but also includes a case where another part is interposed in the middle therebetween. On the contrary, when a part is said to be “directly above” other part, this is interpreted to mean that another part is not interposed in the middle therebetween. Further, when a part of a layer, film, region, plate, or the like is said to be “under” or “below” other part, this not only includes a case where the part is “directly under” the other part, but also includes a case where another part is interposed in the middle therebetween. On the contrary, when a part is said to be “directly under” other part, this is interpreted to mean that another part is not interposed in the middle therebetween.

In one embodiment, there is provided a polishing device including: a surface plate; a polishing pad mounted on the surface plate; a carrier for accommodating a polishing object; and a slurry supply unit including at least one nozzle, wherein the carrier performs a vibrating motion in a trajectory from the center of the surface plate to the end of the surface plate, and the slurry supply unit performs a vibrating motion at the same trajectory and speed as those of the vibrating motion of the carrier.

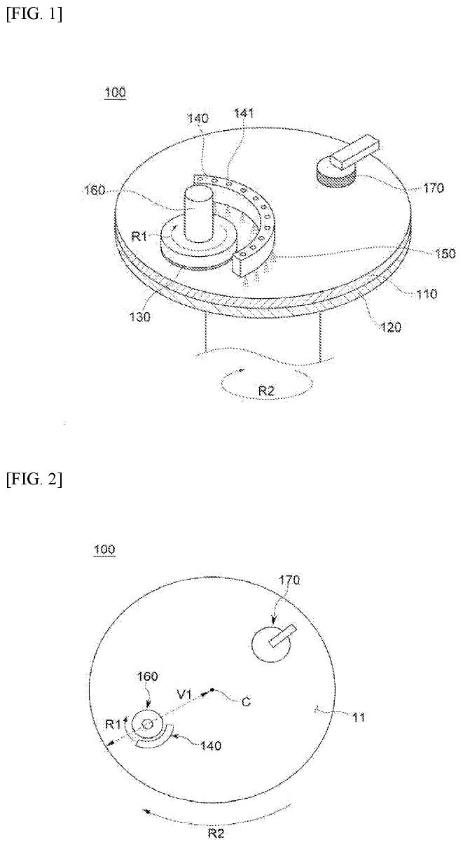

FIG. 1 schematically illustrates a perspective view of the polishing device 100 according to one embodiment, and FIG. 2 schematically illustrates a plan view of the polishing device 110 according to one embodiment. Referring to FIG. 1, the polishing device 100 includes a surface plate 120 and a polishing pad 110 mounted on the surface plate 120. The polishing pad 110 is mounted on the surface plate 120 and performs a rotational motion at the same trajectory and speed at which the surface plate 120 performs a rotational motion.

Referring to FIGS. 1 and 2, the polishing device 100 includes a carrier 160 accommodating a polishing object 130. The carrier 160 rotates in a predetermined rotational direction R1, and the polishing object 130 performs a rotational motion at the same trajectory and speed as the rotational motion of the carrier 160. Further, the carrier 160 performs a vibrating motion in a trajectory (V1, shown by a dotted line in FIG. 2) from the center C of the surface plate 120 to the end of the surface plate 120. When the surface plate 120 performs the rotational motion, and at the same time, the carrier 160 performs the rotational motion and the vibrating motion, the surface to be polished of the polishing object 130 accommodated in the carrier 160 may be polished by efficiently causing friction with the polishing surface 11 of the polishing pad 110 mounted on the surface plate 120.

Further, the polishing device 100 includes a slurry supply unit 140 including at least one nozzle 141. The slurry supply unit 140 serves to supply a slurry onto the polishing surface of the polishing pad 110 to smoothly perform physical and chemical polishing at the interface between the polishing pad 110 and the polishing object 130. The slurry supply unit 140 may be disposed to be spaced apart from the polishing pad 110 at a predetermined height, and may spray the slurry in a direction toward the polishing surface 11 of the polishing pad 110.

The slurry supply unit 140 performs a vibrating motion at the same trajectory V1 and speed as the vibrating motion of the carrier 160. Through this, it may be possible to obtain advantages that the slurry sprayed from the slurry supply unit 140 is uniformly supplied over the entire area of the surface to be polished of the polishing object 130, and at the same time, the amount of the slurry discharged without being effectively utilized is minimized. The conventional slurry supply unit has been a structure for spraying the slurry without a separate vibrating motion at a predetermined position even if it includes only one nozzle or a plurality of nozzles. The slurry sprayed onto the polishing surface of the polishing pad 110 is dispersed over the entire area of the polishing pad 110 by a centrifugal force according to the rotational motion of the surface plate 120 so that it is moved to the interface between the polishing object 130 and the polishing pad 110. In the case of the conventional slurry supply unit structure, since the slurry injection position is fixed, there has been a problem in that a significant amount of the slurry is thrown out to the outside of the polishing pad 110 and discarded before the slurry supplied through this is moved onto the interface between the polishing pad 110 and the polishing object 130. Further, since the slurry sprayed through the nozzle at a fixed position is dispersed only by the centrifugal force according to the rotational motion of the surface plate 120, there has been a problem in that it is difficult to uniformly supply it onto the interface between the polishing object 130 and the polishing pad 110. From this point of view, the polishing device 100 according to one embodiment includes a slurry supply unit 140 including at least one nozzle 141, specifically, a plurality of nozzles 141, and the slurry supply unit 140 is provided with the variability of performing a vibrating motion at the same trajectory and speed as the vibrating motion of the carrier 160, thereby minimizing the amount of the slurry that is thrown out to the outside of the polishing pad 110 and discarded, and allowing the slurry to be uniformly supplied over the entire area of the surface to be polished of the polishing object 130, and as a result, it has the advantage of solving the above-mentioned conventional technical problems. Accordingly, the polishing object 130 polished by the polishing device 100 may satisfy uniform polishing flatness, and may realize an effect in which defects on the surface to be polished do not substantially occur.

Referring to FIGS. 1 and 2, in one embodiment, the carrier 160 may have a circular shaped plane, the slurry supply unit 140 may have an arc shaped plane, and the slurry supply unit 140 may be formed in a form corresponding to the shape of the circumference of the carrier 160. In the present specification, ‘circular shape’ or ‘arc shape’ is interpreted to encompass not only a structure due to a geometrically perfect circle, but also a shape that corresponds to an ellipse according to geometric division, but can be generally recognized as a circle in the corresponding technical field. The fact that the slurry supply unit 140 is formed in a form corresponding to the circumferential shape of the carrier 160 may be interpreted as including not only a case in which the slurry supply unit 140 can be coupled to the circumference of the carrier 160 without gaps, but also a case in which the overall shape of the slurry supply unit 140 corresponds to the carrier although the slurry supply unit 140 is spaced apart from the circumference of the carrier 160 at a predetermined interval. Further, the fact that the slurry supply unit 140 is formed in a form corresponding to the circumferential shape of the carrier 160 may be interpreted to include a case in which the bending direction of the circular shape that is the planar structure of the carrier 160 coincides with the bending direction of the arc shape that is the planar structure of the slurry supply unit 140 although any two points of the slurry supply unit 140 are spaced apart from each other at different intervals from the circumference of the carrier 160. Since the carrier 160 and the slurry supply unit 140 have such a correlation in shape, it may be easy to perform a vibrating motion at the same trajectory and speed as each other, and may be more advantageous in terms of uniformly dispersing the slurry on the interface between the polishing object 130 and the polishing pad 110.

Referring to FIGS. 1 and 2, in one embodiment, the slurry supply unit 140 may be located at the rear of the carrier 160 with respect to the rotation direction R2 of the surface plate 120. In another aspect, an arbitrary point on the polishing surface of the polishing pad 110 may first face the slurry 150 sprayed from the slurry supply unit 140 rather than the surface to be polished of the polishing object 130 mounted on the carrier 160 due to the rotation of the surface plate 120. Through this driving, the polishing surface of the polishing pad 110 in which the slurry 150 sprayed from the slurry supply unit 140 is pre-dispersed may come into contact with the surface to be polished of the polishing object 130, it may be more advantageous in terms of minimizing the amount of the slurry 150 that is thrown out to the outside of the polishing pad 110 and discarded.

In one embodiment, the planar structure of the slurry supply unit 140 may have an arc shape as described above, and it may have a radius of curvature of about 4 inches to about 30 inches, for example, about 5 inches to about 30 inches, for example, about 10 inches to about 30 inches, and for example, about 10 inches to about 25 inches.

In one embodiment, the planar structure of the carrier 160 may have a circular shape as described above, and it may have a diameter of about 100 mm to about 400 mm, for example, about 200 mm to about 400 mm, for example, about 250 mm to about 400 mm, and for example, about 350 mm to about 400 mm.

Since the sizes of the slurry supply unit 140 and the carrier 160 may each or both satisfy the above-described ranges, the polishing surface of the polishing pad 110 may be most efficiently utilized, and an advantage of smooth device driving may be obtained.

The polishing device 100 may further include a controller (not shown) for controlling driving of the slurry supply unit 140. The controller may serve to change the motion method of the slurry supply unit 140, adjust the flow rate of the slurry 150 flown in through at least one nozzle 141 of the slurry supply unit 140, or control whether each of the plurality of nozzles 141 supplies the slurry 150 or not and the flow rate of the slurry 150 flown in.

In one embodiment, the controller may control driving so that a partial rotational motion of the slurry supply unit 140 is performed along a trajectory corresponding to the rotational motion trajectory of the carrier 160 on the assumption that the slurry supply unit 140 is located at the rear of the carrier 160 with respect to the rotation direction of the surface plate 120. When the slurry supply unit 140 includes a plurality of nozzles 141, and a distinct flow rate or whether to open or close is set for each nozzle 141, it may be necessary to adjust the position of the slurry supply unit 140 as needed. The controller controls this driving so that the uniform slurry supply effect by the slurry supply unit 140 may be further improved.

The slurry supply unit 140 may include a plurality of nozzles 141, and the controller may independently control whether to open or close each of the plurality of nozzles 141. It is necessary to flow the slurry into only some of the plurality of nozzles 141 depending on the type, structure, size, or polishing purpose of the polishing object 130 to which the polishing device 100 is applied. In this case, it may be more advantageous to implement excellent polishing performance for various polishing objects 130 by independently controlling whether each of the plurality of nozzles 141 is opened or closed through the controller.

The slurry supply unit 140 may include a plurality of nozzles 141, and the controller may independently control a supply flow rate of the slurry 150 of each of the plurality of nozzles 141. It may be possible to realize more excellent polishing flatness by varying the slurry supply flow rate of the plurality of nozzles 141 depending on the type, structure, size, or polishing purpose of the surface to be polished of the polishing object 130. For example, the slurry supply flow rate of each of the plurality of nozzles 141 may be equally controlled at the beginning of the polishing process, and it may be controlled so that some areas of the surface to be polished of the polishing object 130 are polished faster than other areas by setting the slurry supply flow rate of each of the plurality of nozzles 141 differently for some time from the point when the polishing process is performed for a predetermined time.

When the polishing pad 110 is optimally designed in driving of the polishing device 100, the above-described technical advantages may be maximized. The physical and chemical properties of the polishing surface are determined by the design of the structure and composition of the polishing pad 110. The technical advantage of the polishing device 100 may be maximized by applying a polishing pad 110 designed to be optimized for a driving method in which the carrier 160 and the slurry supply unit 140 perform a vibrating motion at the same time.

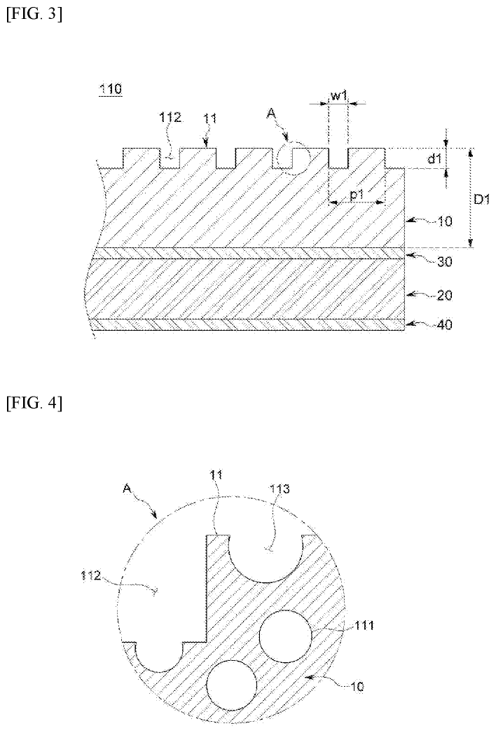

FIG. 3 schematically illustrates a cross section in the thickness direction of the polishing pad 110 according to one embodiment. Referring to FIG. 3, the polishing pad 110 may include a polishing layer 10 having a polishing surface 11, and the polishing surface 11 may include at least one groove 112 having a depth d1 smaller than a thickness D1 of the polishing layer 10. In this case, the groove 112 may have a depth d1 of about 100 μm to about 1,500 μm, and the groove 112 may have a width w1 of about 100 μm to about 1,000 μm.

The groove 112 may serve to control the polishing properties by controlling the fluidity of the slurry provided onto the polishing surface 11 through the slurry supply unit 140, and controlling the size of a direct contact area between the polishing surface 11 and the surface to be polished of the polishing object 130. The depth d1 and width w1 of the groove 112 may each or both satisfy the above-described ranges so that it may be more advantageous to secure fluidity and polishing performance of the slurry optimized for the polishing device having a driving method in which the carrier 160 and the slurry supply unit 140 simultaneously perform a vibrating motion as described above.

More specifically, the groove 112 may have a depth d1 of about 200 μm to about 1,400 μm, for example, about 300 μm to about 1,300 μm, for example, about 400 μm to about 1,200 μm, for example, about 500 μm to about 1,200 μm, and for example, about 700 μm to about 900 μm.

More specifically, the groove 112 may have a width w1 of about 200 μm to about 1,000 μm, for example, about 300 μm to about 800 μm, for example, about 200 μm to about 700 μm, for example, about 300 μm to about 700 μm, and for example, about 400 μm to about 600 μm.

The polishing surface 11 may include two or more grooves 112. In one embodiment, the planar structure of the polishing pad 110 may substantially be a circular shape, and the plurality of grooves 112 may be a concentric circular structure in which they are disposed to be spaced apart from each other at predetermined intervals from the center to the end of the polishing layer 10 on the polishing surface 11. In another embodiment, the plurality of grooves 112 may be a radial structure in which they are continuously formed from the center to the end of the polishing layer 10 on the polishing surface 11. In another embodiment, the plurality of grooves 112 may simultaneously include grooves of a concentric circular structure and grooves of a radial structure.

In one embodiment, the polishing pad 110 may include a polishing layer 10 having a polishing surface 11, the polishing surface 11 may include two or more grooves 112 having a depth d1 smaller than the thickness of the polishing layer 10, and two adjacent grooves 112 may have a pitch p1 therebetween of about 2 mm to about 70 mm. For example, the grooves may each have a pitch p1 of about 2 mm to about 60 mm, for example, about 2 mm to about 50 mm, for example, about 2 mm to about 10 mm, for example, about 1.5 mm to about 5.0 mm, for example, about 1.5 mm to about 4.0 mm, and for example, about 1.5 mm to about 3.0 mm.

The depth d1, width w1, and pitch p1 of the grooves 112 may each or all satisfy the above-described ranges so that it may be more advantageous to secure fluidity and polishing performance of the slurry optimized for the polishing device having a driving method in which the carrier 160 and the slurry supply unit 140 simultaneously perform a vibrating motion as described above.

Referring to FIG. 3, in one embodiment, the polishing layer 10 may have a thickness D1 of about 0.8 mm to about 5.0 mm, for example, about 1.0 mm to about 4.0 mm, for example, about 1.0. mm to 3.0 mm, for example, about 1.5 mm to about 3.0 mm, for example, about 1.7 mm to about 2.7 mm, and for example, about 2.0 mm to about 3.5

FIG. 4 is a schematic diagram illustrating an enlarged portion A of FIG. 3. Referring to FIG. 4, the polishing layer 10 may be a porous structure including a plurality of pores 111. The plurality of pores 111 may be partially exposed to the outside on the polishing surface 11 of the polishing layer 10 to constitute fine concave portions 113 distinct from the grooves 112. The fine concave portions 113 may allow the polishing surface 11 to structurally function as a physical friction surface with respect to the surface to be polished of the polishing object 130 by determining the fluidity and mooring space of the polishing liquid or slurry together with the grooves 112 during use of the polishing pad 100 and giving a predetermined roughness to the polishing surface 11 at the same time. The plurality of pores 111 are dispersed throughout the polishing layer 10, and they may continuously serve to create a predetermined roughness on the surface even in a process of grinding the polishing surface 11 by a conditioner or the like during the polishing process.

The polishing surface 11 may have a predetermined surface roughness due to the fine concave portions 113. In one embodiment, the polishing surface 11 may have a surface roughness Ra of about 1 μm to about 20 μm, for example, about 2 μm to about 18 μm, for example, about 3 μm to about 16 μm, and for example, about 4 μm to about 14 μm. With respect to a driving method in which the carrier 160 and the slurry supply unit 140 simultaneously operate by the polishing surface 11 having such a surface roughness, it may be more advantageous to provide optimal polishing performance for the surface to be polished of the polishing object 130.

The plurality of pores 111 may have an average particle diameter D50 of about 5 μm to about 200 μm, for example, about 20 μm to about 50 μm, for example, about 21 μm to about 50 μm, for example, about 21 μm to about 40 μm, for example, about 21 μm to about 38 μm, and for example, about 23 μm to about 28 μm. The average particle diameter D50 of the plurality of pores 111 may be derived as a number average value of the diameter of the two-dimensional projected image of the exposed pores based on the area 680 μm×480 μm in a picture obtained by photographing at 100 times magnification an arbitrary cross section cut in a direction perpendicular to the thickness direction of the polishing layer 10. In this case, the method for photographing the cross section is not particularly limited, but it may be photographed using, for example, a scanning electron microscope

(SEM). When the plurality of pores 111 have such a size range, the surface roughness exposed on the polishing surface 11 may be optimally designed, and the elastic force provided by the polishing layer 10 to the polishing object 130 may be advantageously secured in an appropriate range in terms of polishing flatness and defect prevention.

The polishing pad 110 may include a polishing layer 10 having a polishing surface 11, and the polishing layer 10, as a layer of providing polishing performance with respect to the polishing object 130 through the polishing surface 11, may be seen as a main component that performs the intrinsic function of the polishing pad 110. The material and structure of the polishing layer 10 are linked to a driving method in which the carrier 160 and the slurry supply unit 140 simultaneously operate, thereby providing appropriate elastic force and rigidity to the surface to be polished of the polishing object 130. Therefore, they may be seen as important factors for excellently realizing the final polishing flatness and polishing rate.

In one embodiment, the polishing layer 10 may include a cured product of a preliminary composition comprising a urethane-based prepolymer. The ‘prepolymer’ refers to a polymer having a relatively low molecular weight in which the polymerization degree is stopped at an intermediate stage to facilitate molding in the production of a cured product. The prepolymer itself may undergo an additional curing process such as heating and/or pressurization, or may be mixed with another polymerizable compound, for example, an additional compound such as a heterogeneous monomer or a heterogeneous prepolymer, reacted, and then molded into a final cured product.

The urethane-based prepolymer may be prepared by reacting an isocyanate compound with a polyol compound. The urethane-based prepolymer may contain a terminal isocyanate group by reacting the isocyanate compound with the polyol compound. Further, the preliminary composition comprising the urethane-based prepolymer may comprise an unreacted isocyanate compound remaining unreacted in the isocyanate compound for preparing the urethane-based prepolymer. Accordingly, the preliminary composition comprising the urethane-based prepolymer may contain the terminal isocyanate group or a free-NCO group derived from the unreacted isocyanate compound. The ‘free-NCO group’ refers to an isocyanate group in a non-urethane-reacted state. The content of the free-NCO group in the preliminary composition is referred to as an ‘isocyanate group content (NCO %)’, and the preliminary composition may have an isocyanate group content (NCO %) of about 5% by weight to about 11% by weight, for example, about 5% by weight to about 10% by weight, for example, about 5% by weight to about 8% by weight, for example, about 8% by weight to about 10% by weight, and for example, about 8.5% by weight to about 10% by weight. The NCO % determines the subsequent curing time and curing rate of the preliminary composition, which determines physical and mechanical properties such as elastic force and rigidity of the polishing layer 10. Since the NCO % of the preliminary composition satisfies the above range, the polishing layer 10 is linked to a driving method in which the carrier 160 and the slurry supply unit 140 simultaneously operate so that the polishing surface 11 having an appropriate elastic force and rigidity may be provided to the surface to be polished of the polishing object 130. As a result, it may be more advantageous to realize excellent polishing performance in terms of a polishing rate for the surface to be polished of the polishing object 130, final polishing flatness, defect prevention, and the like.

One selected from the group consisting of an aromatic diisocyanate, an aliphatic diisocyanate, an alicyclic diisocyanate, and combinations thereof may be used as the isocyanate compound. For example, the isocyanate compound may include an aromatic diisocyanate. For example, the isocyanate compound may include an aromatic diisocyanate and an alicyclic diisocyanate.

The isocyanate compound may include, for example, one selected from the group consisting of 2,4-toluenediisocyanate (2,4-TDI), 2,6-toluenediisocyanate (2,6-TDI) naphthalene-1,5-diisocyanate, p-phenylenediisocyanate, tolidinediisocyanate, 4,4′-diphenylmethanediisocyanate, hexamethylenediisocyanate, dicyclohexylmethanedii socyanate, 4,4′ -di cyclohexylmethanediisocyanate (HINDI), isophorone diisocyanate, and combinations thereof.

The ‘polyol’ refers to a compound containing at least two hydroxyl groups (—OH) per molecule. In one embodiment, the polyol compound may include a dihydric alcohol compound having two hydroxyl groups, that is, diol or glycol; or a trihydric alcohol compound having three hydroxyl groups, that is, a triol compound.

The polyol compound may include, for example, one selected from the group consisting of polyether polyols, polyester polyols, polycarbonate polyols, acrylic polyols, and combinations thereof.

The polyol compound may include, for example, one selected from the group consisting of polytetramethylene ether glycol (PTMG), polypropylene ether glycol, ethylene glycol, 1,2-propylene glycol, 1,3-propylene glycol, 1,2-butanediol, 1,3-butanediol, 2-methyl-1,3-propanediol, 1,4-butanediol, neopentyl glycol, 1,5-pentanediol, 3-methyl-1,5-pentanediol, 1,6-hexanediol, diethylene glycol (DEG), dipropylene glycol (DPG), tripropylene glycol, polypropylene glycol, polypropylene triol, and combinations thereof.

The polyol compound may have a weight average molecular weight (Mw) of about 100 g/mol to about 3,000 g/mol, for example, about 100 g/mol to about 2,000 g/mol, and for example, about 100 g/mol to about 1,800 g/mol.

In one embodiment, the polyol compound may include a low molecular weight polyol having a weight average molecular weight (Mw) of about 100 g/mol or more and about less than 300 g/mol, and a high molecular weight polyol having a weight average molecular weight (Mw) of about 300 g/mol or more and about 1,800 g/mol or less. The high molecular weight polyol may have a weight average molecular weight (Mw) of, for example, about 500 g/mol or more and about 1,800 g/mol or less, for example, about 700 g/mol or more and about 1,800 g/mol or less. In this case, the polyol compound may form an appropriate crosslinking structure in the urethane-based prepolymer, and the polishing layer formed by curing the preliminary composition comprising the urethane-based prepolymer under predetermined process conditions may be more advantageous to implement the above-described effect.

The urethane-based prepolymer may have a weight average molecular weight (Mw) of about 500 g/mol to about 3,000 g/mol, for example, about 600 g/mol to about 2,000 g/mol, and for example, about 800 g /mol to about 1,000 g/mol. When the urethane-based prepolymer has a degree of polymerization corresponding to the above-described weight average molecular weight (Mw), the polishing layer formed by curing the preliminary composition under predetermined process conditions may be more advantageous to realize the aforementioned effects.

In one embodiment, the isocyanate compound may include an aromatic diisocyanate. The aromatic diisocyanate may include, for example, 2,4-toluene diisocyanate (2,4-TDI), for example, 2,4-toluene diisocyanate (2,4-TDI) and 2,6-toluene diisocyanate (2,6-TDI). Further, the polyol compound may include, for example, polytetramethylene ether glycol (PTMG) and diethylene glycol (DEG).

In another embodiment, the isocyanate compound may include an aromatic diisocyanate and an alicyclic diisocyanate. The aromatic diisocyanate may include, for example, 2,4-toluene diisocyanate (2,4-TDI), for example, 2,4-toluene diisocyanate (2,4-TDI) and 2,6-toluene diisocyanate (2,6-TDI). The alicyclic diisocyanate may include, for example, 4,4′-dicyclohexylmethane diisocyanate (HINDI). Further, the polyol compound may include, for example, polytetramethylene ether glycol (PTMG) and diethylene glycol (DEG).

In the preliminary composition, the total amount of the polyol compound may be about 100 parts by weight to about 300 parts by weight, for example, about 100 parts by weight to about 250 parts by weight, for example, about 110 parts by weight to about 250 parts by weight, for example, about 120 parts by weight to about 240 parts by weight, for example, about 120 parts by weight to about 150 parts by weight, and for example, about 180 parts by weight to about 240 parts by weight, compared to 100 parts by weight of the total amount of the isocyanate compound in the total components for preparing the urethane-based prepolymer.

In the preliminary composition, the aromatic diisocyanate that is the isocyanate compound may be contained, the aromatic diisocyanate may include 2,4-TDI and 2,6-TDI, and the aromatic diisocyanate may include 2,6-TDI in an amount of about 1 part by weight to about 40 parts by weight, for example, about 1 part by weight to about 30 parts by weight, for example, about 10 parts by weight to about 30 parts by weight, for example, about 15 parts by weight to about 30 parts by weight, and for example, about 1 part by weight to about 10 parts by weight, compared to 100 parts by weight of 2,4-TDI.

In the preliminary composition, the isocyanate compound may include the aromatic diisocyanate and the alicyclic diisocyanate, and the total content of the alicyclic diisocyanate may be about 0 part by weight to about 30 parts by weight, for example, about 0 part by weight to about 25 parts by weight, for example, about 0 part by weight to about 20 parts by weight, for example, about 5 parts by weight to about 30 parts by weight, for example, about 5 parts by weight to about 25 parts by weight, for example, about 5 parts by weight to about 20 parts by weight, and for example, about 5 parts by weight or more and about less than 15 parts by weight, compared to 100 parts by weight of the total content of the aromatic diisocyanate.

The relative content ratios of the respective components for preparing the urethane-based prepolymer may each or simultaneously satisfy the above-mentioned ranges so that the polishing layer 10 prepared therefrom may provide an appropriate pore structure, surface hardness, elastic force, and rigidity to the surface to be polished of the polishing object 130 through the polishing surface 11. As a result, the polishing layer 10 is linked to a driving method in which the carrier 160 and the slurry supply unit 140 simultaneously operate so that it may be more advantageous for the polishing device 100 to implement excellent polishing performance.

In one embodiment, the preliminary composition may further comprise a curing agent. The curing agent is a component for chemically reacting with the urethane-based prepolymer to form a final cured structure of the polishing layer 10, and may include, for example, an amine compound or an alcohol compound. Specifically, the curing agent may include one selected from the group consisting of aromatic amines, aliphatic amines, aromatic alcohols, aliphatic alcohols, and combinations thereof

The curing agent may include, for example, one selected from the group consisting of 4,4′-methylenebis(2-chloroaniline) (MOCA), diethyltoluenediamine (DETDA), diaminodiphenylmethane, dimethyl thio-toluene diamine (DMTDA), propanediol bis p-aminobenzoate, methylene bis-methylanthranilate, diaminodiphenylsulfone, m-xylylenediamine, isophorone diamine, ethylenediamine, diethylenetriamine, triethylenetetramine, polypropylenediamine, polypropylenetriamine, bis(4-amino-3-chlorophenyl)methane, and combinations thereof.

In one embodiment, the curing agent may include an amine compound, and a molar ratio of a free-NCO group in the preliminary composition to an amine group (—NH₂) in the curing agent may be about 1:0.60 to about 1:0.99, for example, about 1:0.60 to about 1:0.95. The curing time and curing speed of the preliminary composition may be adjusted to optimally secure physical and mechanical properties such as elastic force and rigidity of the polishing layer 10 by determining the amount of the curing agent such that the molar ratio of the free-NCO group in the preliminary composition to the amine group in the curing agent satisfies the above-mentioned range. As a result, the final cured polishing layer 10 is linked to a driving method in which the carrier 160 and the slurry supply unit 140 simultaneously operate so that the polishing surface 11 having an appropriate elastic force and rigidity may be provided to the surface to be polished of the polishing object 130, and it may be more advantageous to realize excellent polishing performance in terms of a polishing rate for the surface to be polished of the polishing object 130, final polishing flatness, defect prevention, and the like.

In one embodiment, the preliminary composition may further comprise a foaming agent. The foaming agent may include one selected from the group consisting of a solid-phase foaming agent, a gas-phase foaming agent, a liquid-phase foaming agent, and combinations thereof as a component for forming a pore structure in the polishing layer 10. For example, the foaming agent may include a solid-phase foaming agent, a gas-phase foaming agent, or a combination thereof.

The solid-phase foaming agent may have an average particle diameter of about 5 μm to about 200 μm, for example, about 20 μm to about 50 μm, for example, about 21 μm to about 50 μm, and for example, about 21 μm to about 40 μm. When the solid-phase foaming agent is thermally expanded particles as described below, the average particle diameter of the solid-phase foaming agent may mean an average particle diameter of the thermally expanded particles themselves. When the solid-phase foaming agent is unexpanded particles as described below, the average particle diameter of the solid-phase foaming agent may mean an average particle diameter of the particles after being expanded by heat or pressure. When the average particle diameter of the solid-phase foaming agent satisfies the above range, it is advantageous to mix it without agglomeration when the solid-phase foaming agent is mixed in the preliminary composition, and as a result, it may be advantageous to form an appropriately dispersed pore structure in the polishing layer 10.

The solid-phase foaming agent may contain expandable particles. The expandable particles are particles having properties of being expandable by heat or pressure, and the size thereof in the final polishing layer may be determined by heat or pressure applied during the manufacturing process of the polishing layer. The expandable particles may include thermally expanded particles, unexpanded particles, or a combination thereof. The thermally expanded particles are particles pre-expanded by heat, and refer to particles having a small or almost no size change due to heat or pressure applied during the manufacturing process of the polishing layer. The unexpanded particles are particles that have not been pre-expanded, and refer to particles which are expanded by heat or pressure applied during the manufacturing process of the polishing layer to determine their final size.

The expandable particles may include: a resin material shell; and an expansion-inducing component present in the inside encapsulated by the shell.

For example, the shell may include a thermoplastic resin, and the thermoplastic resin may be one or more selected from the group consisting of a vinylidene chloride-based copolymer, an acrylonitrile-based copolymer, a methacrylonitrile-based copolymer, and an acrylic copolymer.

The expansion-inducing component may include one selected from the group consisting of a hydrocarbon compound, a chlorofluoro compound, a tetraalkylsilane compound, and combinations thereof.

Specifically, the hydrocarbon compound may include one selected from the group consisting of ethane, ethylene, propane, propene, n-butane, isobutane, n-butene, isobutene, n-pentane, isopentane, neopentane, n-hexane, heptane, petroleum ether, and combinations thereof.

The chlorofluoro compound may include one selected from the group consisting of trichlorofluoromethane (CCl₃F), dichlorodifluoromethane (CCl₂F₂), chlorotrifluoromethane (CClF₃), tetrafluoroethylene (CClF₂-CClF₂), and combinations thereof.

The tetraalkylsilane compound may include one selected from the group consisting of tetramethyl silane, trimethylethylsilane, trimethylisopropylsilane, trimethyl-n-propylsilane, and combinations thereof.

The solid-phase foaming agent may optionally include inorganic component-treated particles. For example, the solid-phase foaming agent may contain inorganic component-treated expandable particles. In one embodiment, the solid-phase foaming agent may contain silica (SiO₂) particle-treated expandable particles. The inorganic component treatment of the solid-phase foaming agent may prevent agglomeration between a plurality of particles. The inorganic component-treated solid-phase foaming agent may have different chemical, electrical, and/or physical properties on the foaming agent surface from the inorganic component-untreated solid-phase foaming agent.

The solid-phase foaming agent may be contained in an amount of about 0.5 parts by weight to about 10 parts by weight, for example, about 1 part by weight to about 3 parts by weight, for example, about 1.3 parts by weight to about 2.7 parts by weight, and for example, about 1.3 parts by weight to about 2.6 parts by weight, based on 100 parts by weight of the preliminary composition. As the content of the solid-phase foaming agent satisfies the above range, it is advantageous to mix it without agglomeration when the solid-phase foaming agent is mixed in the preliminary composition. As a result, it may be advantageous to form an appropriately dispersed pore structure in the polishing layer 10.

The gas-phase foaming agent may include an inert gas. The gas-phase foaming agent may be used as a pore-forming element by being injected during a process in which the urethane-based prepolymer and the curing agent are reacted.

The type of the inert gas is not particularly limited as long as it is a gas that does not participate in the reaction between the urethane-based prepolymer and the curing agent. For example, the inert gas may include one selected from the group consisting of nitrogen gas (N₂), argon gas (Ar), helium gas (He), and combinations thereof. Specifically, the inert gas may include nitrogen gas (N₂) or argon gas (Ar).

In one embodiment, the foaming agent may include a solid-phase foaming agent. For example, the foaming agent may consist only of a solid-phase foaming agent.

The solid-phase foaming agent may contain expandable particles, and the expandable particles may include thermally expanded particles. For example, the solid-phase foaming agent may consist only of thermally expanded particles. When the solid-phase foaming agent consists only of the thermally expanded particles without containing the unexpanded particles, the variability of the pore structure decreases, but the predictability increases so that it may be advantageous to implement homogeneous pore properties over the entire region of the polishing layer.

In one embodiment, the thermally expanded particles may be particles having an average particle diameter of about 5 μm to about 200 μm. The thermally expanded particles may have an average particle diameter of about 5 μm to about 100 μm, for example, about 10 μm to about 80 μm, for example, about 20 μm to about 70 μm, for example, about 20 μm to about 50 μm, for example, about 30 μm to about 70 μm, for example, about 25 μm to about 45 μm, for example, about 40 μm to about 70 μm, and for example, about 40 μm to about 60 μm. The average particle diameter is defined as D50 of the thermally expanded particles.

In one embodiment, the thermally expanded particles may have a density of about 30 kg/m³ to about 80 kg/m³, for example, about 35 kg/m³ to about 80 kg/m³, for example, about 35 kg/m³ to about 75 kg/m³, for example, about 38 kg/m³ to about 72 kg/m³, for example, about 40 kg/m³ to about 75 kg/m³, and for example, about 40 kg/m³ to about 72 g/m³.

In one embodiment, the foaming agent may include a gas-phase foaming agent. For example, the foaming agent may include a solid-phase foaming agent and a gas-phase foaming agent. Matters regarding the solid-phase foaming agent are the same as described above.

The gas-phase foaming agent may be injected through a predetermined injection line during a process in which the urethane-based prepolymer, the solid-phase foaming agent, and the curing agent are mixed. The gas-phase foaming agent may have an injection rate of about 0.8 L/min to about 2.0 L/min, for example, about 0.8 L/min to about 1.8 L/min, for example, about 0.8 L/min to about 1.7 L/min, for example, about 1.0 L/min to about 2.0 L/min, for example, about 1.0 L/min to about 1.8 L/min, and for example, about 1.0 L/min to about 1.7 L/min.

The preliminary composition may further comprise an additive as needed. The type of the additive may include one selected from the group consisting of a surfactant, a pH adjuster, a binder, an antioxidant, a heat stabilizer, a dispersion stabilizer, and combinations thereof. The names referring to additives such as ‘surfactant’ and ‘antioxidant’ are arbitrary names based on the main role of the corresponding material, and each corresponding material does not necessarily perform only a function limited to the role indicated by the name.

The surfactant is not particularly limited as long as it is a material that serves to prevent a phenomenon such as agglomeration or overlapping of pores. For example, the surfactant may include a silicone-based surfactant.

The surfactant may be used in an amount of about 0.2 parts by weight to about 2 parts by weight based on 100 parts by weight of the preliminary composition. Specifically, the surfactant may be contained in an amount of about 0.2 parts by weight to about 1.9 parts by weight, for example, about 0.2 parts by weight to about 1.8 parts by weight, for example, about 0.2 parts by weight to about 1.7 parts by weight, for example, about 0.2 parts by weight to about 1.6 parts by weight, for example, about 0.2 parts by weight to about 1.5 parts by weight, and for example, about 0.5 parts by weight to about 1.5 parts by weight, based on 100 parts by weight of the second urethane-based prepolymer. When the surfactant is contained in an amount within the above range, pores derived from the gas-phase foaming agent may be stably formed and maintained in the mold.

The reaction rate controlling agent serves to promote or delay the reaction, and a reaction accelerator, a reaction retarder, or both thereof may be used depending on the purpose. The reaction rate controlling agent may include a reaction accelerator. For example, the reaction accelerator may be one or more reaction accelerators selected from the group consisting of a tertiary amine-based compound and an organometallic compound.

Specifically, the reaction rate controlling agent may include one or more selected from the group consisting of triethylenediamine, dimethylethanolamine, tetramethylbutanediamine, 2-methyl-triethylenediamine, dimethylcyclohexylamine, triethylamine, triisopropanolamine, 1,4-diazabicyclo(2,2,2)octane, bis(2-methylaminoethyl)ether, trimethylaminoethylethanolamine, N,N,N′,N″,N′″-pentamethyldiethylenetriamine, dimethylaminoethylamine, dimethylaminopropylamine, benzyldimethylamine, N-ethylmorpholine, N,N-dimethylaminoethylmorpholine, N,N-dimethylcyclohexylamine, 2-methyl-2-azanovonein, dibutyltin dilaurate, stannous octoate, dibutyltin diacetate, dioctyltin diacetate, dibutyltin maleate, dibutyltin di-2-ethylhexanoate, and dibutyltin dimercaptide. Specifically, the reaction rate controlling agent may include one or more selected from the group consisting of benzyldimethylamine, N,N-dimethylcyclohexylamine, and triethylamine.

The reaction rate controlling agent may be used in an amount of about 0.05 parts by weight to about 2 parts by weight, for example, about 0.05 parts by weight to about 1.8 parts by weight, for example, about 0.05 parts by weight to about 1.7 parts by weight, for example, about 0.05 parts by weight to about 1.6 parts by weight, for example, about 0.1 parts by weight to about 1.5 parts by weight, for example, about 0.1 parts by weight to about 0.3 parts by weight, for example, about 0.2 parts by weight to about 1.8 parts by weight, for example, about 0.2 parts by weight to about 1.7 parts by weight, for example, about 0.2 parts by weight to about 1.6 parts by weight, for example, about 0.2 parts by weight to about 1.5 parts by weight, and for example, about 0.5 parts by weight to about 1 part by weight, based on 100 parts by weight of the preliminary composition. When the reaction rate controlling agent is used in the aforementioned amount range, the polishing layer having the desired pore size and hardness may be formed by appropriately controlling the curing reaction rate of the preliminary composition.

Referring to FIG. 3, the polishing pad 110 may further include a support layer 20 disposed on the rear surface of the polishing surface 11 of the polishing layer 10. The support layer 20 may play a buffer role of appropriately adjusting the pressure and impact transmitted to the polishing object 130 through the polishing surface 11 during the polishing process while structurally supporting the polishing layer 10. Through this, the support layer 20 may contribute to preventing the occurrence of damage and defects to the polishing object 130 in the polishing process to which the polishing pad 110 is applied.

The above-described buffering effect may be maximized in a driving method in which the carrier 160 and the slurry supply unit 140 simultaneously operate by appropriately designing the structure and material of the support layer 20. In one embodiment, the support layer 20 may include a nonwoven fabric or suede, but is not limited thereto. For example, the support layer 20 may include a nonwoven fabric. The ‘nonwoven fabric’ refers to a three-dimensional reticular structure of nonwoven fibers. Specifically, the support layer 20 may include a nonwoven fabric and a resin impregnated in the nonwoven fabric.

The nonwoven fabric may be, for example, a nonwoven fabric of fibers including one selected from the group consisting of polyester fibers, polyamide fibers, polypropylene fibers, polyethylene fibers, and combinations thereof.

The resin impregnated in the nonwoven fabric may include, for example, one selected from the group consisting of a polyurethane resin, a polybutadiene resin, a styrene-butadiene copolymer resin, a styrene-butadiene-styrene copolymer resin, an acrylonitrile-butadiene copolymer resin, a styrene-ethylene-butadiene-styrene copolymer resin, a silicone rubber resin, a polyester-based elastomer resin, a polyamide-based elastomer resin, and combinations thereof In one embodiment, the support layer 20 may include a nonwoven fabric of fibers including polyester fibers impregnated with a resin including a polyurethane resin.

The support layer 20 may have a thickness of, for example, about 0.5 mm to about 2.5 mm, for example, about 0.8 mm to about 2.5 mm, for example, about 1.0 mm to about 2.5 mm, for example, about 1.0 mm to about 2.0 mm, and for example, about 1.2 mm to about 1.8 mm.

The support layer 20 may have a density of about 0.1 g/cm³ to about 1.0 g/cm³, for example, about 0.1 g/cm³ to about 0.8 g/cm³, for example, about 0.1 g/cm³ to about 0.6 g/cm³, and for example, about 0.2 g/cm³ to about 0.4 g/cm³. When the density satisfies such a range, it may be more advantageous for the support layer 20 to provide a suitable buffering effect corresponding to the pressurization conditions of the carrier 160 optimized for the slurry supply unit 140 that supplies the slurry through a plurality of nozzles 141 unlike as in the conventional art.

Referring to FIG. 3, the polishing pad 110 may include a first adhesive layer 30 for attaching the polishing layer 10 and the support layer 20. Specifically, the first adhesive layer 40 may include one selected from the group consisting of a urethane-based adhesive, an acrylic adhesive, a silicone-based adhesive, and combinations thereof, but is not limited thereto.

Referring to FIGS. 1 and 3, the polishing pad 110 may further include a second adhesive layer 40 for attaching the bottom surface of the support layer 20 and the surface plate 120. The second adhesive layer 50 is a medium for attaching the polishing pads 100, 200, and 300 and the surface plate of the polishing device, and may be derived from, for example, a pressure sensitive adhesive (PSA), but is not limited thereto.

Referring to FIGS. 1 and 2, the polishing device 100 may further include a conditioner 170. The conditioner 170 may serve to control the polishing pad 110 to maintain the polishing surface 11 in a state suitable for polishing throughout the polishing process. The polishing object 130 is polished while being pressurized to the polishing surface 11 by the carrier 160 under predetermined conditions. Accordingly, as the polishing process continues, the shape of the polishing surface 11 is changed while it is physically being pressed by receiving a pressure. The fine concave portions 113 of the polishing surface 11 provide a physical friction force with respect to the surface to be polished of the polishing object 130. As such fine concave portions 113 are physically pressed, the effect of providing the frictional force may gradually decline. Accordingly, the polishing surface 11 may continuously maintain a predetermined surface roughness by roughening the polishing surface 11 through the conditioner 170.

The conditioner 170 may include a plurality of cutting tips which protrude toward the polishing surface 11 and are formed to be spaced apart from each other. The plurality of cutting tips may be, for example, a polygonal truncated pyramid shape.

The conditioner 170 may process the polishing surface 11 while performing a rotating motion. The rotation direction of the conditioner 170 may be the same as or different from the rotation direction R2 of the surface plate 120. The conditioner 170 may have a rotation speed of, for example, about 50 rpm to about 150 rpm, for example, about 80 rpm to about 120 rpm.

In one embodiment, the conditioner 170 may process the polishing surface 11 while being pressurized against the polishing surface 11. The pressurization pressure of the conditioner 170 against the polishing surface 11 may be, for example, about 1 lbf to about 12 lbf, and for example, about 3 lbf to about 9 lbf. When the conditioner 170 is processing-driven against the polishing surface 11 under predetermined pressurization conditions, the groove structure and surface roughness of the polishing surface 11 may be maintained at appropriate levels throughout the polishing process, and through this, physical and chemical polishing between the surface to be polished of the polishing object 130 and the polishing surface 11 is combined with a simultaneous vibration driving method of the carrier 160 and the slurry supply unit 140 including the plurality of nozzles 141 so that it may be more advantageous in realizing optimal polishing performance.

In another embodiment, there is provided a method for manufacturing a semiconductor device, the method comprising steps of: mounting a polishing pad on a surface plate; mounting a polishing object on a carrier; disposing a polishing surface of the polishing pad and a surface to be polished of the polishing object to be in contact with each other and then respectively rotating the surface plate and the carrier under pressurized conditions to polish the polishing object; and supplying a slurry onto the polishing surface of the polishing pad from a slurry supply unit including at least one nozzle, wherein the polishing object includes a semiconductor substrate, the carrier performs a vibrating motion in a trajectory from the center of the surface plate to the end of the surface plate, and the slurry supply unit performs a vibrating motion at the same trajectory and speed as those of the vibrating motion of the carrier.

Explaining in another aspect, the method for manufacturing the semiconductor device relates to a method for manufacturing a semiconductor device by applying the polishing device 100 according to the above-described description with reference to FIGS. 1 to 4. That is, the details and technical advantages of matters regarding the polishing device 100 and all sub-configurations thereof described above with reference to FIGS. 1 to 4 may all be integrally applied to the following descriptions regarding the method for manufacturing the semiconductor device not only when repeatedly described later, but also when not repeatedly described later.

In the method for manufacturing the semiconductor device, the polishing object 130 may include a semiconductor substrate. The semiconductor substrate may include one selected from the group consisting of a silicon oxide film, a silicon nitride film, a tungsten film, a tungsten oxide film, a tungsten nitride film, a copper film, a copper oxide film, a copper nitride film, a titanium film, a titanium oxide film, a titanium nitride film, and combinations thereof as a surface to be polished. When the semiconductor substrate including such a film is used as the polishing object 130, polishing results of an appropriate polishing rate, high polishing flatness, and low defect occurrence may be obtained through a polishing method in which a slurry supply unit 140 including at least one nozzle 141 is applied to the surface to be polished of the polishing object 130, and to which a driving method where the slurry supply unit 140 and the carrier 160 perform a vibrating motion at the same trajectory and speed is applied.

The step of mounting the polishing pad 110 on the surface plate 120 may be a step of mounting the rear surface of the polishing surface 11 of the polishing pad 110 to be attached to the surface plate 120. In one embodiment, the rear surface of the polishing surface 11 and the surface plate 120 may be attached via a pressure-sensitive adhesive as a medium.

The step of mounting the polishing object 130 on the carrier 160 may be a step of mounting the surface to be polished of the polishing object 130 to face the polishing surface 11. The polishing object 130 may be mounted on the carrier 160 in a non-adhesive manner.

The step of polishing the polishing object 130 may be performed by disposing the polishing surface 11 of the polishing pad 110 and the surface to be polished of the polishing object 130 to be in contact with each other and then respectively rotating the surface plate 120 and the carrier 160 under pressurized conditions. The polishing surface 11 and the surface to be polished may come into direct contact with each other, or may come into indirect contact with each other via a slurry component provided through the slurry supply unit 140, for example, abrasive particles as a medium. In the present specification, ‘contacting’ is construed to include all cases of direct or indirect contact.

The carrier 160 may be polished while it is being pressurized against the polishing surface 11 under predetermined pressurization conditions. At this time, the pressurization load of the carrier 160 against the polishing surface 11 may be about 0.01 psi to about 20 psi, for example, about 0.1 psi to about 15 psi. When the pressurization load of the carrier 160 against the polishing surface 11 satisfies the above range, physical and chemical polishing between the surface to be polished of the semiconductor substrate including the above-described film and the polishing surface 11 satisfying the groove structure and surface roughness is combined with a simultaneous vibration driving method of the carrier 160 and the slurry supply unit 140 including the plurality of nozzles 141 so that it may be more advantageous in realizing optimal polishing performance.

The surface plate 120 and the carrier 160 may rotate respectively. The rotation direction of the surface plate 120 and the rotation direction of the carrier 160 may be the same as or different from each other as a clockwise direction or a counterclockwise direction.

When the surface plate 120 rotates, the polishing pad 110 mounted thereon may also rotate at the same trajectory and speed. The surface plate 120 may have a rotation speed of, for example, about 50 rpm to about 150 rpm, for example, about 80 rpm to about 120 rpm, and for example, about 90 rpm to about 120 rpm. When the rotation speed of the surface plate 120 satisfies the above range, polishing of the semiconductor substrate including the above-described film is combined with a simultaneous vibration driving method of the carrier 160 and the slurry supply unit 140 including the plurality of nozzles 141 so that it may be more advantageous in realizing optimal polishing performance.

The carrier 160 may have a rotation speed of about 10 rpm to about 500 rpm, for example, about 30 rpm to about 200 rpm, for example, about 50 rpm to about 100 rpm, and for example, about 50 rpm to about 90 rpm. When the rotation speed of the carrier 160 satisfies the above range, polishing of the semiconductor substrate including the above-described film is combined with a simultaneous vibration driving method of the carrier 160 and the slurry supply unit 140 including the plurality of nozzles 141 so that it may be more advantageous in realizing optimal polishing performance.

Referring to FIGS. 1 and 2, the carrier 160 may perform a vibrating motion in a trajectory V1 from the center (C) of the surface plate 120 to the end of the surface plate 120, and the slurry supply unit 140 may perform a vibrating motion at the same trajectory V1 and speed as those of the vibrating motion of the carrier 160. The slurry supply unit 140 applies the variability in which it performs the vibrating motion at the same trajectory and speed as those of the vibrating motion of the carrier 160, thereby minimizing the amount of the slurry that is thrown out to the outside of the polishing pad 110 and discarded, and allowing the slurry to be uniformly supplied over the entire area of the surface to be polished of the polishing object 130. As a result, the polishing object 130 polished by the method for manufacturing a semiconductor device may satisfy a uniform polishing flatness, and may realize the effect that defects on the surface to be polished do not substantially occur.

The carrier 160 and the slurry supply unit 140 may have a vibrating motion speed of about 1 inch/sec to about 20 inch/sec, for example, about 1 inch/sec to about 15 inch/sec, for example, about 1 inch/sec to about 12 inch/sec, for example, about 1 inch/sec to about 10 inch/sec, and for example, about 1 inch/sec to about 5 inch/sec. When the vibrating motion is performed in the above speed range, it may be advantageous to minimize the amount of the slurry that is thrown out to the outside and discarded, and it may be more advantageous in terms of uniformly providing the slurry over the entire area of the surface to be polished of the polishing object 130.

In the method for manufacturing a semiconductor device, the polishing object 130 may include a semiconductor substrate, the slurry supply unit 140 may include a plurality of nozzles 141, and the injection amount of the slurry 150 through each of the plurality of nozzles 141 may be independently adjusted in a range of about 0 ml/min to about 1,000 ml/min. Specifically, whether each of the plurality of nozzles 141 is opened or closed may be independently controlled. In the case of the nozzle 141 among the plurality of nozzles 141, into which the slurry is injected, it may have an injection amount of about 10 ml/min to about 800 ml/min, for example, about 50 ml/min to about 500 ml/min. When such a supply flow rate is applied, but each nozzle is independently controlled, such that it may be more advantageous to obtain polishing results of an appropriate polishing rate, high polishing flatness, and low defect occurrence in polishing a semiconductor substrate including the above-described type of film.

The method for manufacturing a semiconductor device may further comprise a step of processing the polishing surface through a conditioner. The polishing object 130 is polished while it is being pressurized against the polishing surface 11 under predetermined conditions by the carrier 160. Accordingly, as the polishing process continues, the shape of the polishing surface 11 is changed while it is physically being pressed by receiving a pressure. The fine concave portions 113 of the polishing surface 11 provide a physical friction force with respect to the surface to be polished of the polishing object 130, and as such fine concave portions 113 are physically pressed, the effect of providing the frictional force may gradually decline. Accordingly, the polishing surface 11 may maintain a predetermined surface roughness by roughening the polishing surface 11 through the conditioner 170.

The conditioner 170 may include a plurality of cutting tips which protrude toward the polishing surface 11 and are formed to be spaced apart from each other. The plurality of cutting tips may be, for example, a polygonal truncated pyramid shape.

The conditioner 170 may process the polishing surface 11 while performing a rotating motion. The rotation direction of the conditioner 170 may be the same as or different from the rotation direction R2 of the surface plate 120. The conditioner 170 may have a rotation speed of about 50 rpm to about 150 rpm, for example, about 80 rpm to about 120 rpm. When the rotation speed of the conditioner 170 satisfies the above range, it may be more advantageous to maintain the surface roughness of the polishing surface 11 at an appropriate level in polishing the semiconductor substrate including the above-described film. Further, in relation to the simultaneous vibration driving method of the carrier 160 and the slurry supply unit 140 including the plurality of nozzles 141, the surface state of the polishing surface 11 processed by the conditioner 170 may be more advantageous to appropriately secure the slurry fluidity.

The conditioner 170 may process the polishing surface 11 while it is being pressurized against the polishing surface 11. In this case, the pressurization pressure of the conditioner 170 applied against the polishing surface 11 may be, for example, about 1 lbf to about 12 lbf, and for example, about 3 lbf to about 9 lbf. When the pressurization load of the conditioner 170 against the polishing surface 11 satisfies the above range, the groove structure and surface roughness of the polishing surface 11 may be maintained at appropriate levels throughout the polishing process, and through this, physical and chemical polishing between the polishing surface 11 and the surface to be polished of the semiconductor substrate including the above-described film is combined with the simultaneous vibration driving method of the carrier 160 and the slurry supply unit 140 including the plurality of nozzles 141 so that it may be more advantageous in realizing optimal polishing performance.

The polishing device according to one embodiment includes a slurry supply unit enabling subdivided driving in the supply of the polishing slurry, and the driving of the slurry supply unit has the advantage of enabling optimized driving in an organic relationship between rotation and/or vibrating motion of the carrier and the surface plate and the vertical pressurization conditions, etc. for the polishing surface of the carrier.

Further, the method for manufacturing a semiconductor device, to which the polishing device according to one embodiment is applied, can be an effective technical means of obtaining a high-quality semiconductor device by providing optimal polishing performance in manufacturing of a semiconductor device, in which sophisticated process control is very important compared to other products.

### EXPLANATION OF REFERENCE NUMERALS

110: Polishing pad
11: Polishing surface
111: Pore
112: Groove
113: Fine concave portion
w1: Groove width
d1: Groove depth
p1: Groove pitch
10: Polishing layer
20: Support layer
30: First adhesive layer
40: Second adhesive layer
D1: Polishing layer thickness
120: Surface plate
130: Polishing object
140: Slurry supply unit
141: Nozzle
150: Slurry
160: Carrier
170: Conditioner
C: Center of surface plate
V1: Vibrating motion direction of carrier
R1: Rotational motion direction of carrier
R2: Rotational motion direction of surface plate

What is claimed is:

1. A polishing device comprising:
a surface plate;
a polishing pad mounted on the surface plate;
a carrier for accommodating a polishing object; and
a slurry supply unit including at least one nozzle,
wherein the carrier performs a vibrating motion in a trajectory from the center of the surface plate to the end of the surface plate, and the slurry supply unit performs a vibrating motion at the same trajectory and speed as those of the vibrating motion of the carrier.

2. The polishing device of claim 1, wherein the carrier has a circular shaped plane, and the slurry supply unit has a circular arc shaped plane.

3. The polishing device of claim 1, wherein the slurry supply unit is positioned to be spaced apart from the circumference of the carrier at a predetermined interval, and is formed in a form corresponding to the shape of the circumference of the carrier.

4. The polishing device of claim 1, wherein the slurry supply unit is located at the rear of the carrier with respect to the rotation direction of the surface plate.

5. The polishing device of claim 1, wherein the slurry supply unit has a radius of curvature of 4 inches to 30 inches, and the carrier has a diameter of 100 mm to 400 mm.

6. The polishing device of claim 1, wherein the polishing pad includes a polishing layer having a polishing surface, the polishing surface includes at least one groove having a depth smaller than a thickness of the polishing layer, the groove has a depth of 100 μm to 1,500 μm, and the groove has a width of 100 μm to 1,000 μm.

7. The polishing device of claim 1, wherein the polishing pad includes a polishing layer having a polishing surface, the polishing surface includes two or more grooves having a depth smaller than the thickness of the polishing layer, and two adjacent grooves have a pitch therebetween of 2 mm to 70 mm.

8. The polishing device of claim 1, wherein the polishing pad includes a polishing layer having a polishing surface, the polishing surface includes two or more plurality of grooves, and the plurality of grooves are a concentric circular structure in which the plurality of grooves are disposed to be spaced apart from each other at predetermined intervals from the center to the end of the polishing layer on the polishing surface.

9. The polishing device of claim 1, wherein the polishing layer has a thickness of 0.8 mm to 5.0 mm.

10. The polishing device of claim 1, wherein the polishing layer is a porous structure including a plurality of pores.

11. The polishing device of claim 1, wherein the polishing pad includes a polishing layer having a polishing surface, the polishing layer includes a cured product of a preliminary composition comprising a urethane-based prepolymer, and the preliminary composition has an isocyanate group content (NCO%) of 5% by weight to 11% by weight.

12. The polishing device of claim 1, wherein the slurry supply unit supplies a slurry onto the polishing surface of the polishing pad.

13. The polishing device of claim 1, further comprising a controller for controlling driving of the slurry supply unit.

14. The polishing device of claim 13, wherein the controller controls driving so that a partial rotational motion of the slurry supply unit is performed along a trajectory corresponding to the rotational motion trajectory of the carrier.

15. The polishing device of claim 13, wherein the slurry supply unit includes a plurality of nozzles, and the controller independently controls whether to open or close each of the plurality of nozzles.

16. The polishing device of claim 13, wherein the slurry supply unit includes a plurality of nozzles, and the controller independently controls a supply flow rate of the slurry of each of the plurality of nozzles.

17. A method for manufacturing a semiconductor device, the method comprising steps of:
mounting a polishing pad on a surface plate;
mounting a polishing object on a carrier;
disposing a polishing surface of the polishing pad and a surface to be polished of the polishing object to be in contact with each other and then respectively rotating the surface plate and the carrier under pressurized conditions to polish the polishing object; and
supplying a slurry onto the polishing surface of the polishing pad from a slurry supply unit including at least one nozzle,
wherein the polishing object includes a semiconductor substrate, the carrier performs a vibrating motion in a trajectory from the center of the surface plate to the end of the surface plate, and the slurry supply unit performs a vibrating motion at the same trajectory and speed as those of the vibrating motion of the carrier.

18. The method of claim 17, wherein the slurry supply unit includes a plurality of nozzles, and the amount of the slurry injected through each nozzle is independently adjusted in a range of 0 ml/min to 1,000 ml/min.

19. The method of claim 17, wherein the surface plate has a rotation speed of 50 rpm to 150 rpm.

20. The method of claim 17, wherein the carrier has a rotation speed of 10 rpm to 500 rpm.
